(19) United States
(12) Patent Application Publication
(10) Pub. No.: US 2016/0090293 A1
(43) Pub. Date: Mar. 31, 2016

(54) MICROELECTROMECHANICAL SYSTEMS (MEMS) AUDIO SENSOR-BASED PROXIMITY SENSOR

(71) Applicant: INVENSENSE, INC., San Jose, CA (US)

(72) Inventor: Omid Oliaei, Sunnyvale, CA (US)

(21) Appl. No.: 14/497,164

(22) Filed: Sep. 25, 2014

(51) Int. Cl. B81B 7/00; H04R 1/08; G01B 17/00

(52) U.S. Cl. CPC B81B 7/00; G01B 17/00; H04R 1/08; B81B 2201/0257; H04R 2201/003

(57) ABSTRACT

Microelectromechanical systems (MEMS) acoustic sensors associated with proximity detection are described. Provided implementations can comprise a MEMS acoustic sensor element associated with a transmitter and a receiver. The transmitter transmits acoustic signals for reflection off a surface. The receiver receives the reflected acoustic signals and determines a proximity of the surface. Functions of a device are controlled according to the determined proximity.

### TECHNICAL FIELD

The subject disclosure relates to microelectromechanical systems (MEMS), more particularly, a MEMS microphone-based proximity sensor.

### BACKGROUND

Conventionally, proximity sensors are used to detect or sense a proximity (e.g., near or far) between the proximity sensor and an object. Such proximity sensors are used to detect when an object, such as a person, is in close proximity relative to the proximity sensors. Further, such proximity sensors are designed to detect an external object that is located outside the detectable range of a touch sensor (e.g., a touch screen or touch sensitive surface). To enable proximity detection, proximity sensors utilize an infrared (IR) beam (or field) emitter and an IR receiver or detector. The emitted IR signal will reflect of an external object (if present). If the reflected IR signal is received by the IR receiver, such proximity sensors determine whether the object is in close proximity or far proximity. Such a determination can include determining that the amount of reflected IR light exceeds a certain threshold.

IR proximity sensors can be optimized for different objects. For example, the cellular phone industry uses IR proximity sensors to detect the presence of a user, specifically the user's head. When an object is within a specified distance, the cellular phone can disable a touch screen of the cell phone during a phone call.

Traditional proximity sensors often utilize about significant amounts of current in the range of hundreds of micro amps on average. Further, these proximity sensors are subject to inaccuracies due to light reflections or dispersions, such as due to contaminants on the surface of a device. Additionally, the operation of such proximity sensors is adversely affected by ambient light, temperature variation, texture of objects, color of objects, and other factors.

It is thus desired to provide MEMS proximity sensors that improve upon these and various other deficiencies. The above-described deficiencies of MEMS proximity sensors are merely intended to provide an overview of some of the problems of conventional implementations, and are not intended to be exhaustive. Other problems with conventional implementations and techniques and corresponding benefits of the various aspects described herein may become apparent upon review of the following description.

### SUMMARY

The following presents a simplified summary of the specification to provide a basic understanding of some aspects of the specification. This summary is not an extensive overview of the specification. It is intended to neither identify key or critical elements of the specification nor delineate any scope particular to any embodiments of the specification, or any scope of the claims. Its sole purpose is to present some concepts of the specification in a simplified form as a prelude to the more detailed description that is presented later.

In a non-limiting example, a system comprising a MEMS proximity sensor determines whether an object is in proximity with the MEMS proximity sensor based on an acoustic signal, according to aspects of the subject disclosure. The MEMS proximity sensor can be an audio sensor or a microphone. The system can comprise a transmitter that generates a pulse signal (e.g., audio signal, ultrasonic signal) and a receiver that receives a reflected pulse signal. The system can determine a proximity of a surface or object based on the received reflected pulse signal. The system can manage other functions or components based on the determined proximity.

Moreover, an exemplary method associated with a MEMS proximity sensor is described. The method can comprise generating a pulse signal via a transmitter of the MEMS proximity sensor. In another aspect, the method can comprise receiving a reflected signal via a receiver of the MEMS proximity sensor or a receiver of another MEMS proximity sensor. The method can determine a proximity of an object based on the reflected signal. In another aspect, a device is controlled according to the determined proximity.

The following description and the drawings set forth certain illustrative aspects of the specification. These aspects are indicative, however, of but a few of the various ways in which the principles of the specification may be employed. Other advantages and novel features of the specification will become apparent from the following detailed description of the specification when considered in conjunction with the drawings.

### BRIEF DESCRIPTION OF THE DRAWINGS

Numerous aspects, embodiments, objects and advantages of the present invention will be apparent upon consideration of the following detailed description, taken in conjunction with the accompanying drawings, in which like reference characters refer to like parts throughout, and in which:

FIG. 1 depicts a non-limiting schematic block diagram of a microelectromechanical systems (MEMS) proximity detection system, according to various non-limiting aspects of the subject disclosure;

FIG. 2 depicts a further non-limiting schematic diagram of a MEMS proximity detection system associated with a mobile device, according to further non-limiting aspects of the subject disclosure;

FIG. 3 depicts a further non-limiting schematic diagram of a MEMS proximity detection system, including a calibration component, according to further non-limiting aspects as described herein;

FIG. 4 depicts a further non-limiting schematic diagram of an exemplary MEMS proximity detection system associated with a transmitter and receiver, according to other non-limiting aspects of the subject disclosure;

FIG. 5 depicts a further non-limiting block diagram of an exemplary MEMS proximity detection system, including a filter component, according to various non-limiting aspects of the subject disclosure;

FIG. 6 depicts an exemplary flowchart of non-limiting methods associated with a MEMS proximity detection system configured for determining a proximity, according to various non-limiting aspects of the disclosed subject matter;

FIG. 7 depicts an exemplary flowchart of non-limiting methods associated with a two-sensor MEMS proximity detection system configured for determining a proximity, according to various non-limiting aspects of the disclosed subject matter;

FIG. 8 depicts an exemplary flowchart of non-limiting methods associated with a MEMS proximity detection system configured for calibrating a proximity detection process, according to various non-limiting aspects of the disclosed subject matter;

FIG. 9 depicts an example schematic block diagram for a computing environment in accordance with certain embodiments of this disclosure; and

FIG. 10 depicts an example block diagram of a computer network operable to execute certain embodiments of this disclosure.

### DETAILED DESCRIPTION

### Overview

While a brief overview is provided, certain aspects of the subject disclosure are described or depicted herein for the purposes of illustration and not limitation. Thus, variations of the disclosed embodiments as suggested by the disclosed apparatuses, systems and methodologies are intended to be encompassed within the scope of the subject matter disclosed herein. For example, the various embodiments of the apparatuses, techniques and methods of the subject disclosure are described in the context of MEMS pressure sensors. However, as further detailed below, various exemplary implementations can be applied to other areas of MEMS sensor design and packaging, without departing from the subject matter described herein.

As used herein, the terms MEMS proximity sensor(s), MEMS microphone(s), MEMS audio sensor, and the like are used interchangeably unless context warrants a particular distinction among such terms. For instance, the terms can refer to MEMS devices or components that can measure a proximity, acoustic characteristics, or the like.

Additionally, terms such as “at the same time,” “common time,” “simultaneous,” “simultaneously,” “concurrently,” “substantially simultaneously,” “immediate,” and the like are employed interchangeably throughout, unless context warrants particular distinctions among the terms. It should be appreciated that such terms can refer to times relative to each other and may not refer to an exactly simultaneously action(s). For example, system limitations (e.g., download speed, processor speed, memory access speed, etc.) can account for delays or unsynchronized actions. In other embodiments, such terms can refer to acts or actions occurring within a period that does not exceed a defined threshold amount of time.

Traditional proximity sensing devices typically involve generating an IR beam or radiation and detecting a reflection of the generated IR beam. Such devices require constant power consumption when active. Further, traditional IR proximity sensors can be negatively affected by light, temperature, characteristics of objects/surfaces, and the like. In addition, such IR proximity detectors are often limited to a single purpose or use. For example, conventional IR proximity sensors require specialized IR beam generators and IR beam receivers.

The system of the present invention can operate at less than about 100 micro amps or even less than about tens of micro amps. Compared with hundreds of micro amps required by typical IR sensors, systems and methods described herein can provide valuable power savings. Thus, systems and methods of the present invention may be ideal for the always on concept in which a microphone is always on to detect whether an object is or has arrived in close proximity.

To these and/or related ends, various aspects of MEMS proximity sensor systems, methods, and apparatuses that detect acoustic signals are described herein. For instance, exemplary implementations can provide a MEMS proximity sensor system that comprises one or more acoustic sensors or microphones. In an aspect, the one or more acoustic sensors can generate acoustic signals (e.g., ultrasonic signals) and receive reflected acoustic signals. In non-limiting implementations, a MEMS proximity sensor system can determine whether an object is within a threshold distance (e.g., close proximity) of the system.

As a non-limiting example, exemplary embodiments the MEMS proximity sensor system can comprise a single acoustic sensor that can generate acoustic signals and receive acoustic signals. The acoustic sensor can alternate between a generating state and a listening state to facilitate proximity detections. In another non-limiting example, exemplary embodiments the MEMS proximity sensor system can comprise multiple acoustic sensors. Each acoustic sensor may be dedicated to one or more of generating an acoustic signal or listening for an acoustic signal.

Furthermore, a controller can control various circuitry, components, and the like, to facilitate proximity detection. For instance, the controller can comprise a processing device (e.g., computer processor) that controls generation of signals, modes of operation and the like. Additionally, embodiments disclosed herein may be comprised in larger systems or apparatuses. For instance, aspects of this disclosure can be employed in smart televisions, smart phones or other cellular phones, wearables (e.g., watches, headphones, etc.), tablet computers, laptop computers, desktop computers, digital recording devices, appliances, home electronics, handheld gaming devices, remote controllers (e.g., video game controllers, television controllers, etc.), automotive devices, personal electronic equipment, medical devices, industrial systems, bathroom fixtures (e.g., faucets, toilets, hand dryers, etc.), printing devices, cameras, and various other devices or fields.

Aspects of systems, apparatuses or processes explained in this disclosure can constitute machine-executable components embodied within machine(s), hardware components, or hardware components in combination with machine executable components, e.g., embodied in one or more computer readable mediums (or media) associated with one or more machines. Such components, when executed by the one or more machines, e.g., computer(s), computing device(s), virtual machine(s), etc. can cause the machine(s) to perform the operations described. While the various components are illustrated as separate components, it is noted that the various components can be comprised of one or more other components. Further, it is noted that the embodiments can comprise additional components not shown for sake of brevity. Additionally, various aspects described herein may be performed by one device or two or more devices in communication with each other.

To that end, the one or more processors can execute code instructions stored in memory, for example, volatile memory and/or nonvolatile memory. By way of illustration, and not limitation, nonvolatile memory can include read only memory (ROM), programmable ROM (PROM), electrically programmable ROM (EPROM), electrically erasable PROM (EEPROM), or flash memory. Volatile memory can include random access memory (RAM), which acts as external cache memory. By way of illustration and not limitation, RAM is available in many forms such as static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). The memory (e.g., data stores, databases) of the subject systems and methods is intended to comprise, without being limited to, these and any other suitable types of memory.

As it employed in the subject specification, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Processors can exploit nano-scale architectures such as, but not limited to, molecular and quantum-dot based transistors, switches and gates, in order to optimize space usage or enhance performance of user equipment. A processor may also be implemented as a combination of computing processing units.

### Exemplary Embodiments

Various aspects or features of the subject disclosure are described with reference to the drawings, wherein like reference numerals are used to refer to like elements throughout. In this specification, numerous specific details are set forth in order to provide a thorough understanding of the subject disclosure. It should be understood, however, that the certain aspects of disclosure may be practiced without these specific details, or with other methods, components, parameters, etc. In other instances, well-known structures and devices are shown in block diagram form to facilitate description and illustration of the various embodiments.

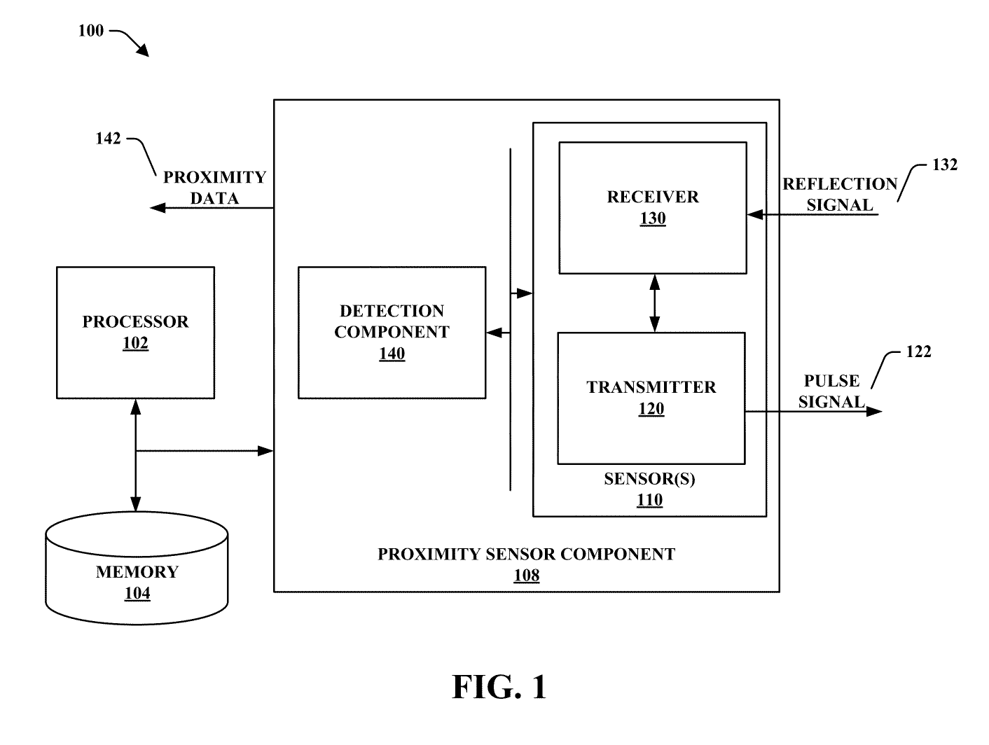

Accordingly, FIG. 1 depicts a non-limiting block diagrams of a system 100 capable of detecting a proximity of a surface, according to various non-limiting aspects of the subject disclosure. It is to be appreciated that system 100 can be used in connection with implementing one or more systems or components shown and described in connection with other figures disclosed herein. It is noted that all or some aspects of system 100 can be comprised in larger systems such as servers, computing devices, smart phones, laptop computers, personal digital assistants, remote controllers, headphones, and the like. Further, it is noted that the embodiments can comprise additional components not shown for sake of brevity. Additionally, various aspects described herein may be performed by one device or two or more devices in communication with each other.

System 100 can include a memory 104 that stores computer executable components and a processor 102 that executes computer executable components stored in the memory 104. It is to be appreciated that system 100 can be used in connection with implementing one or more of the systems or components shown and described in connection with other figures disclosed herein. Proximity sensor component 108 can comprise a sensor(s) 110 (which can generate and/or received pulse signals) and a detection component 140 (which can determine whether a surface is in proximity with a particular reference point, such as sensor 110).

As depicted, sensor 110 can comprise a transmitter 120 and a receiver 130. Transmitter 120 and a receiver 130 can comprise one or more audio sensors, such as a MEMS microphone. For instance, transmitter 120 can comprise a MEMS microphone configured to generate an audio signal and/or ultrasonic signal (e.g., pulse signal 122) for proximity detection, distance measurements, and/or to execute various other actions. Likewise, receiver 130 can comprise another MEMS microphone configured to receive a pulse signal (e.g., reflected signal 132) for proximity detection, distance measurements, and/or to execute various other actions. It is noted that the one or more audio sensors can be omni-directional (e.g., signals coming from all directions can be received), unidirectional (e.g., signals coming from less than all directions can be received), or the like. Likewise, the one or more audio sensors can be reciprocal, that is, transmitter 120 and receiver 130 can each act as both a transmitter and a receiver. It is noted that various combination of different types of MEMS microphones can be utilized as long as a MEMS microphone can generate the pulse signal 122 and a MEMS microphone (or the same MEMS microphone) can receive reflected signal 132 from the desired direction(s) for determining proximity.

It is noted that sensor(s) 110 can comprise one or more sensing elements. Such sensing elements can include membranes, diaphragms, or other elements capable of sensing and/or generating pulse signals. For instance, one or more membranes of sensor(s) 110 can be excited to transmit a pulse signal. In another aspect, the one or more membranes of sensor(s) 110 can receive pulse signals that induce movement of the one or more membranes. Furthermore, such sensing elements may be embodied within or coupled to hardware, such as a single integrated circuit (IC) chip, multiple ICs, an ASIC, or the like. In various aspects, an ASIC can include or can be coupled to a processor, transmitter 120, and receiver 130.

In various embodiments, receiver 130 can be positioned or configured to detect pulse signals from one or more determined directions. For instance, a mobile phone can comprise receiver 130 positioned to receive reflected signal 132 when a user has the mobile phone next to their ear (e.g., in a talking position). In many mobile phone applications, the user has the mobile phone next to their ear such that a screen or interface of the mobile phone is facing the user. In such mobile phone applications, the receiver 130 may be configured to receive reflected signal 132 coming in a direction towards the screen or interface. In various other examples, receiver 130 can be positioned or configured to receive reflected signal 132 from other desired directions. For instance, in an automobile application, receiver 130 may be configured to receive reflected signal 132 coming from the direction of a particular seat (e.g., driver's seat, passenger's seat, etc.), a position in front of a display column, a position in front of a control, etc. It is noted that more than one receiver 130 can be utilized to determine a proximity. Thus, proximity can be determined along with a direction.

Transmitter 120 can comprise an amplifier and/or other circuitry for generating a signal. For instance, an amplifier of transmitter 120 can generate a signal (e.g., pulse signal 122) to be propagated for proximity detection. Pulse signal 122 can be a modulated sinusoidal wave signal or the like and can be of a determined frequency. The frequency can be virtually any frequency in the audio spectrum or not in the audio spectrum (e.g., ultrasound). For instance, pulse signal 122 can be an ultrasound pulse outside of the human hearing spectrum. In other embodiments, the pulse signal can be of a frequency such that animals or a particular type of animal (e.g., dog) cannot hear the audio signal. Frequencies in the human audible ranges can be utilized, however, as a practical matter, humans may find the audible signal annoying or interfering (e.g., such as with a telephone conversation). Likewise, frequencies in the canine audible ranges, for example, can be utilized but certain applications may not be practically suited for such frequencies. For example, an electronic device emitting an audible signal in the canine audible ranges may be more prone to damage from canines or may irritate such canines. Accordingly, while the various embodiments described herein refer to pulse signals, ultrasound signals, and/or audio signals, such embodiments may utilize any signal that audio sensors (e.g., MEMS microphones, etc.) can receive.

In various embodiments, transmitter 120 can be configured to generate ultrasound pulse signals at frequencies determined according to properties of sensor 110, such as sensitivity, power consumption, and the like. For instance, receiver 130 can have different ranges of sensitivity. Frequencies within a given range may be associated with low sensitivity of receiver 130, while frequencies of a different range may be associated with higher sensitivity of receiver 130 and transmitter 120 can be configured to generate signals in a desired range based on the sensitivity of receiver 130. In another aspect, certain frequency ranges can be associated with different power consumptions. For example, low frequencies can be associated with increased power consumption by sensor 110 (e.g., via transmitter 120, receiver 130, or both). In at least one embodiment, system 100 can generate (e.g., transmit by transmitter 120) signals of about twenty two kilohertz (kHz) up to about 80-85 kHz. While pulse signals are generally referred to herein and select ranges may be referenced, it is noted that a generated signal can be various other types of signals having various properties.

According to an aspect of the present invention, system 100 can detect an object that itself is emitting an acoustic signal (e.g., ultrasound pulses). For example, a phone or wearable emitting ultrasound signals may come into close vicinity of another phone or wearable that may detect its presence. In another aspect, system 100 can be activated based on information received from another device and/or another component within a device (e.g., a speaker that can generate pulse signal 122). For instance, a key fob or remote can send a signal to system 100. The signal may be an ultrasonic signal or any other type of signal. System 100 can activate a proximity detection process based on information received from the key fob. In another aspect, a device can comprise a first component (e.g., a speaker) that generates a signal and a second component (e.g., a receiver) or system 100 that can detect the signal generated by the speaker.

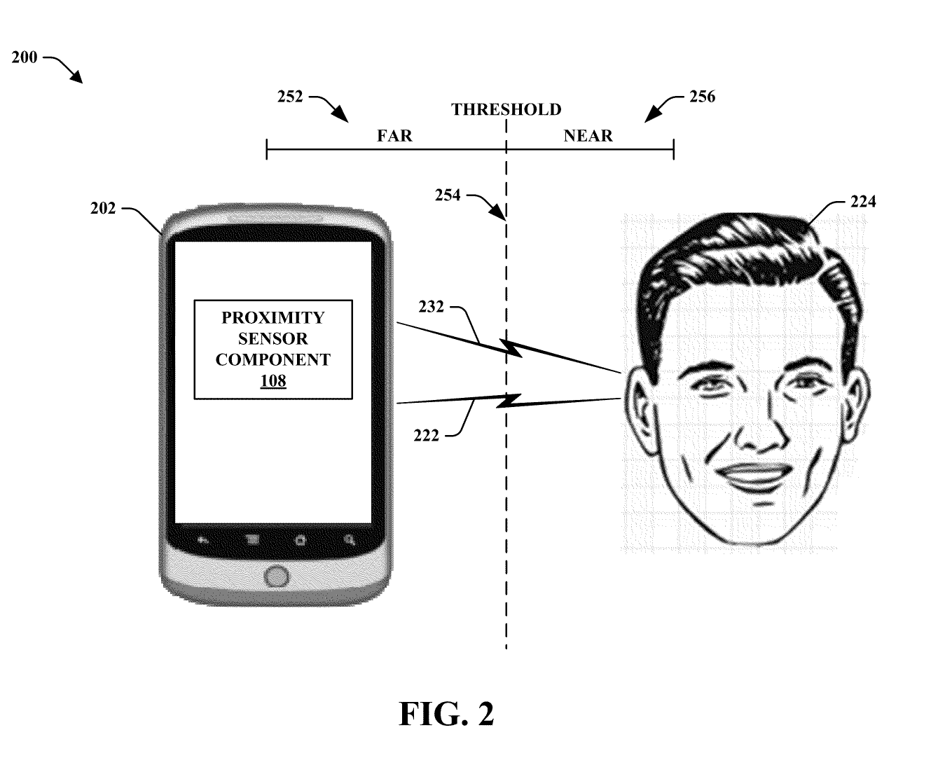

Turning to FIG. 2, with reference to FIG. 1, there depicted is an exemplary high level diagram of a proximity sensing system 200 for determining a proximity of a user to a mobile device. As depicted system 200 can comprise mobile device 202 (which comprises all or some components of proximity sensor component 108). It is noted that system 200 can comprise various other components not shown for brevity. While FIG. 1 depicts a smart phone, mobile device 202 can comprise various user equipment devices. Likewise, while FIG. 2 depicts user 224, other objects or surface can be utilized.

User 224 can interact with or be in the general location of mobile device 202. Mobile device 202 can generate (e.g., via transmitter 120) an ultrasound signal 222 (e.g., ultrasonic signal). The ultrasound signal 222 can reflect off user 224 and be received by device 202 (e.g., via receiver 130) as a reflected signal 232. In embodiments, reflected signal 232 will be received or detected after some amount of time delay. For instance, reflected signal 232 reflects or bounces off user 224 with some attenuation and is picked up or received by the receiver 130.

In an aspect, detection component 140 can determine a proximity (e.g., near, far, etc.) and/or estimate of a distance of an object (e.g., user 224) with reference to another object (e.g., mobile device 202), such as via a counter, processor 102, or the like. According to at least one embodiment of the subject disclosure, proximity can be determined in a binary fashion, such as near or far. For example, transmitter 120 can generate a number of pulses (e.g., pulse sequence or pulse count). Receiver 130 can receive reflected signal 132 and monitor a number of received pulses, such as in a given time period. In another aspect, a pulse can be a received from another component such as via pulses from a clock. For example, transmitter 120 can generate a signal and a clock can generate clock pulses. Detection component 140 can count (e.g., via a counter, processor 102, or the like) a number of clock pulses between transmission and reception of one or all of the generated signals. In an aspect, if a pulse count is above a threshold number (e.g., a number, percentage, etc.), then it is determined that user 224 (or any other object) is in a close vicinity, such as within ten millimeters (mm), 10 centimeters (cm), or the like.

It is noted that detection component 140 can utilize various processes for determining proximity and/or distance. For instance, detection component 140 can utilize a “time of flight” process that measures a time between a pulse being transmitted (e.g., as ultrasound signal 222) and the pulse being received (e.g., as reflected signal 232). In an aspect, the measured time(s) can be utilized to determine a proximity and/or distance. As another example, detection component 140 can determine proximity and/or distance based on parameters associated with reflected signal 232. For instance, the parameter can be a time associated with time of flight of the reflected signals (e.g., pulse count). In at least one embodiment, detection component 140 can determine a proximity based on alterations detected in reflected signal 232, and the like. For instance, mobile device 202 can be configured to determine a proximity based on a modulated signal and/or encoded to facilitate detection of the reflected signal or alter (e.g., enhance) the detection accuracy. In another aspect, mobile device 202 can be configured to determine a proximity based on a signal energy parameter. As such, detection component 140 can be calibrated according to the modulation scheme and/or signal energy. In another aspect, detection component 140 can utilize auto-correlation processes or computations, cross-correlation processes or computations, demodulation processes, or other processes to facilitate determining a proximity. In at least one embodiment, detection component 140 can utilize algorithms (e.g., executed by a processor 102 and stored in memory 104) to determine proximity or distance. For instance, the processor may use a search algorithm to determine the proximity or distance of the object.

While various embodiments described herein may refer to determining a proximity or a distance, it is noted that such embodiments can be utilized to determine proximity and/or distance. However, for sake of brevity the embodiments may reference one of proximity and/or distance.

A threshold number of pulses can be associated with a threshold distance 254. For example, proximity sensor component 108 can be calibrated such that a number of pulses representing the proximity of user 224 under a threshold number of pulses can be associated with a distance described as far 252 (e.g., over ten mm). Likewise, if the number of pulses meets or exceeds the threshold number of pulses, the distance can be described as near 256 (e.g., within ten mm). It is noted that the threshold number of pulses can be a predetermined number of pulses or can be dynamically determined, such as through user input or determined based on a calibration process. In various embodiments, the threshold number of pulses can be application specific and/or based on parameters of sensor(s) 110. For instance, a threshold number of pulses can be higher for more sensitive sensors and relatively lower for less sensitive sensors. In another aspect, the threshold number of pulses can be different for applications requiring a closer threshold distance (e.g., 5 mm. 5 cm, etc,) than for applications requiring a relatively further threshold distance (e.g., 15 mm, 15 cm, etc.). For example, mobile device 202 can require a close distance when detecting proximity during a conversation and may require a relatively greater distance during other operations.

In another aspect, proximity sensor component 108 can generate output (proximity data 142). Proximity data 142 can be utilized according to desired applications (e.g., hand held electronic applications, automotive applications, medical applications, wearable electronics applications, etc.). While FIG. 2 depicts an embodiment for a binary determination (e.g., near or far), various other applications can utilize a different number of distances or proximities (e.g., near, intermediate, far). It is noted that other embodiments can utilize various nomenclatures and/or can determine distances (or ranges of distance) or estimate distance.

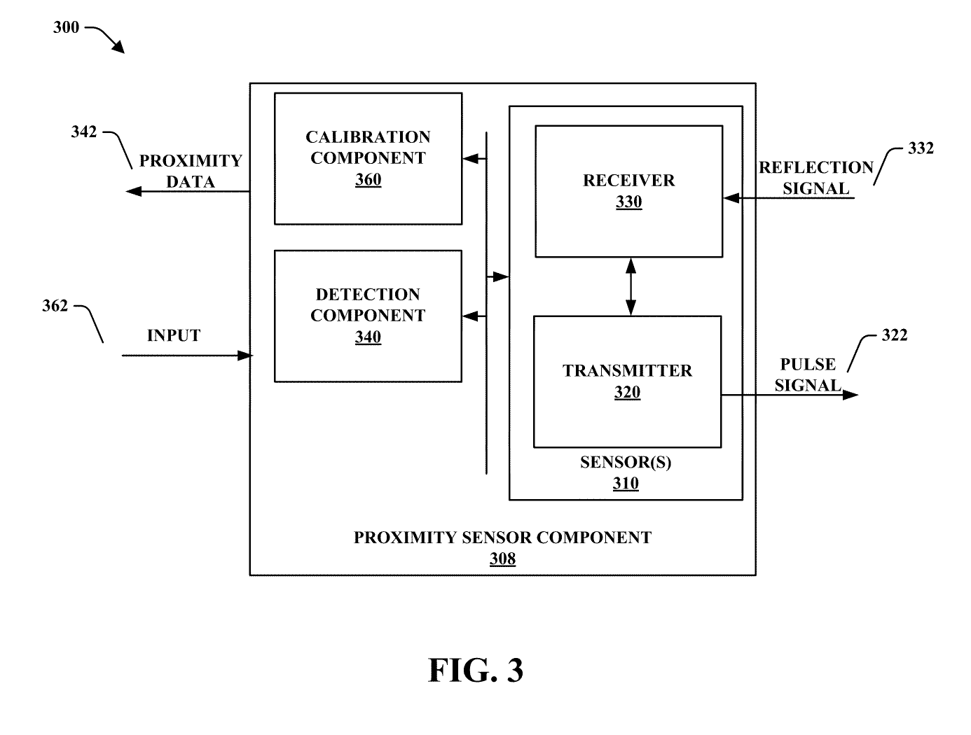

Turning now to FIG. 3, there depicted is a system 300 that can calibrate proximity detection in accordance with various embodiments described herein. While, system 300 is depicted as comprising a number of components, it is noted that system 300 can comprise various other components (not shown). Furthermore, while components are depicted as separate components, it is further noted that the various components can be comprised in one or more components. It is to be appreciated that system 300 can be used in connection with implementing one or more of the systems or components shown and described in connection with other figures disclosed herein. Moreover, like named components associated with the various figures described herein can perform similar or identical functions and/or comprise similar or identical circuitry, logic, and the like. For example, sensor(s) 310 can perform substantially similar functions as sensor(s) 110 and/or can comprise substantially similar devices and/or circuitry (e.g., MEMS microphone(s) and/or audio sensors).

In another aspect, system 300 can include a memory (shown) that stores computer executable components and a processor (not shown) that executes computer executable components stored in the memory. Proximity sensor component 308 can comprise a sensor(s) 310 (which can generate and/or received ultrasound signals), a detection component 340 (which can determine whether a surface is in proximity with a particular reference point, such as sensor 310), and a calibration component 360 (which can calibrate aspects of system 300 for proximity detection).

Calibration component 360 calibrates various parameters for proximity detections. For instance, calibration component 360 can alter a threshold number of received pulses based on various factors, such as a desired application, power consumption, sensitivity of one or more of receiver 330 or transmitter 320, user input (e.g., input 362), and the like. In an example, proximity sensor component 308 can utilize a default threshold number of pulses for determining proximity of an object. A user can desire to change a distance associated with determining proximity (e.g., near or far). The user can provide input 362 (e.g., via an interface). For instance, a user can hold a cell phone a determined distance from a surface (e.g., the user's face) and can provide input indicating that the current distance should be the threshold. Calibration component 360 can utilize input 362 to appropriately adjust a threshold number of received pulses.

In another aspect, calibration component 360 can calibrate or alter a frequency or number of pulses of pulse signal 322. In an aspect, the frequency or number of pulses can be adjusted based on a tradeoff scheme that optimally or nearly optimally adjusts operating parameters to achieve a desired level of power consumption, sensitivity, and/or other metrics. It is noted that calibration component 360 can utilize various machine learning or programming techniques to facilitate calibration.

In order to provide for or aid in the numerous inferences described herein, system 300 can examine the entirety or a subset of the data to which it is granted access and can provide for reasoning about or infer states of the system, environment, etc. from a set of observations as captured via events and/or data. The inferences can provide for calibrating frequencies, calibrating thresholds, or can generate a probability distribution over states, for example. The inference can be probabilistic—that is, the computation of a probability distribution over states of interest based on a consideration of data and events. An inference can also refer to techniques employed for composing higher-level events from a set of events and/or data.

Such an inference can result in the construction of new events or actions from a set of observed events and/or stored event data, whether or not the events are correlated in close temporal proximity, and whether the events and data come from one or several event and data sources. Various classifications (explicitly and/or implicitly trained) schemes and/or systems (e.g., support vector machines, neural networks, expert systems, Bayesian belief networks, fuzzy logic, data fusion engines, etc.) can be employed in connection with performing automatic and/or inferred actions in connection with the claimed subject matter.

A classifier can map an input attribute vector, x=(x1, x2, x3, x4, xn), to a confidence that the input belongs to a class, such as by f(x)=confidence(class). Such classification can employ a probabilistic and/or statistical-based analysis (e.g., factoring into the analysis utilities and costs) to infer an action that a user desires to be automatically performed. A support vector machine (SVM) is an example of a classifier that can be employed. The SVM operates by finding a hyper-surface in the space of possible inputs, where the hyper-surface attempts to split the triggering criteria from the non-triggering events. Intuitively, this makes the classification correct for testing data that is near, but not identical to training data. Other directed and undirected model classification approaches include, e.g., naïve Bayes, Bayesian networks, decision trees, neural networks, fuzzy logic models, and probabilistic classification models providing different patterns of independence can be employed. Classification as used herein also is inclusive of statistical regression that is utilized to develop models of priority.

In a non limiting example, with reference to FIG. 2, user 224 can position mobile device 202 a desired distance away from the user 224 (or another surface). The user 224 can provide input 362 indicating that the user 224 desires the current position to be associated with a threshold distance such that if the distance between the mobile device 202 and the user 224 meets the threshold distance or is between the threshold distance and the user 224, then system 300 should determine proximity to be near. Calibration component 360 can utilize a test set of pulses to determine proper thresholds and/or other metrics. It is noted that the user 224 can provide other input 362 for calibrating a threshold distance, such as input associated with increasing or decreasing a distance (e.g., through interaction with an interface, etc.).

According to various other embodiments, calibration component 360 can calibrate various other parameters associated with proximity sensor component 308. For instance, calibration component 360 can calibrate sensitivity of detection, power metrics, defined ranges of proximity, define rules when proximity is detected (e.g., toggle detection on/off), and the like. In another aspect, calibration component 360 can determine actions to perform in response to determining a proximity. The actions can include, for example, enabling/disabling an interface or display, enabling/disabling available operations, performing operations (e.g., alerting a user when a door is open or ajar, etc.), and the like. It is noted that the actions can be predetermined and/or dynamically determined (e.g., based on user input, based on a history of use, etc.). For example, if a user shakes a device (e.g., signaling frustration) during a call, the system 300 can monitor a history associated with such events. The system 300 can learn whether control of an interface based on proximity detection is a cause of the frustration and calibration component 360 can dynamically recalibrate the proximity detection process. In another aspect, the system 300 can prompt a user for input associated with calibration based on the history of use.

As a non-limiting example, an automobile can comprise proximity sensor component 308 in an interface (e.g., door handle/latch, control console, passenger detection for safety systems, etc.). In this example, proximity sensor component 308 can be positioned relative to a passenger seat. If proximity sensor component 308 detects that a user or passenger is in the passenger seat, then the proximity sensor component 308 can provide appropriate proximity data 342 to an interface. The proximity data 342 can comprise instructions or can be utilized to generate instructions to control certain functions, such as a light to indicate the passenger has or has not engaged a safety harness.

As another non-limiting example, a printer or other device can utilize system 300. The printer or other device can determine whether paper is in a tray, a level or amount of paper in a tray, whether a latch/door is open, and the like. It is noted that proximity detection can be applied in various other situations and/or devices. As such, embodiments described herein are utilized for exemplary purposes and are deemed to be not limiting.

In various embodiments, detection component 340 can comprise or utilize other devices and/or components to affect a process for determining proximity. For instance, detection component 340 can utilize input from gyroscopes, accelerometers, light sensors, pressure or weight sensors, temperature sensors, motion detectors, and the like. In an aspect, a gyroscope can determine an orientation of a device relative to a user. Detection component 340 can utilize the orientation and/or other information (e.g., current functions of a device, etc.) to selectively determine a threshold and/or method associated with determining proximity. For example, if a device is in a horizontal configuration while a media item is in playback, the proximity may be associated with a first threshold. If the device is in a vertical orientation and in a “speaker phone” operation, detection component 340 can utilize a second threshold for determining proximity. In another aspect, detection component 340 can utilize the orientation and the determined proximity to control availability of functions of devices. For example, if a near proximity is determined when a device is in a horizontal orientation, certain functions of the device (e.g., display screen, back light, etc.) can be enabled and/or disabled. Moreover, user defined rules and/or default rules can be applied to determine a proximity or available functions based in part on input from such components.

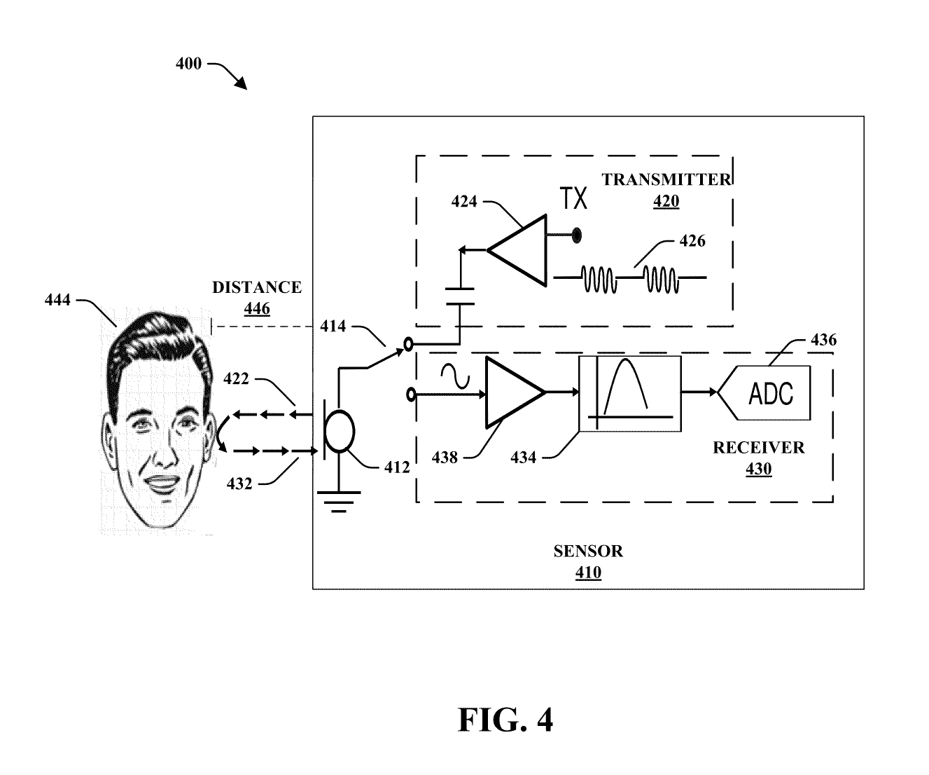

Turning now to FIG. 4, there illustrated is a system 400, including a microphone (e.g., MEMS microphone) that can determine a proximity in accordance with various embodiments described herein. While, system 400 is depicted as comprising a number of components and/or circuitry, it is noted that system 400 can comprise various other components, circuitry, or other arrangements of circuitry/components (not shown). It is to be appreciated that system 400 can be used in connection with implementing one or more of the systems or components shown and described in connection with other figures disclosed herein (e.g., system 100, 200, 300, etc.). Moreover, like named components associated with the various figures described herein can perform similar or identical functions and/or comprise similar or identical circuitry, logic, and the like. For example, sensor 410 can perform substantially similar functions as sensor(s) 110, 310, etc. and/or can comprise substantially similar devices and/or circuitry (e.g., MEMS microphone(s) and/or audio sensors).

System 400 can primarily comprise a sensor 410. The sensor 410 can comprise a transmitter 420 (which can generate ultrasound signals), a receiver 430 (which can receive ultrasound signals), a sensing element 412 (e.g., membrane, diaphragm, or other element capable of transmitting/receiving ultrasound signals) and a control switch 414. As depicted, sensor 410 can comprise a single audio sensor, such as a MEMS microphone. However, it is noted that sensor 410 can comprise any number of audio sensors, such as a first audio sensor comprising transmitter 420 and a second audio sensor comprising receiver 430. Each audio sensor can be selectively or programmably used as a transmitter or a receiver. It is noted that the microphones can be the same or different from each other in terms of their structures and the manner in which they are coupled to an environment and/or system 400.

Transmitter 420 can generate acoustic signals, such as ultrasonic signals. Transmitter 420 can comprise an amplifier 424 that amplifies a signal 426 to generate ultrasound signal 422. As described in various embodiments herein, ultrasound signal 422 can be an ultrasound signal having any range of frequencies. In various aspects, transmitter 420 can generate the ultrasound signal 422 such that the ultrasound signal 422 has a determined number of pulses. In a non-limiting operation, transmitter 420 can generate ultrasound signal 422 when control switch 414 is connected to a transmission path. Transmitter 420 can transmit or broadcast ultrasound signal 422 and pulses of the ultrasound signal 422 can reflect or refract off of reflective surface 444. It is noted that reflective surface 444 can comprise any number of surfaces. Such surfaces can include users, objects, other sensors, and the like. Moreover, the term “reflective” does not refer to a surface having a specific reflection capability (e.g., mirror, glass, etc.). Rather, reflective is used to describe an action of reflecting off a surface.

Ultrasound signal 422 can be reflected as reflected signal 432. While ultrasound signal 422 and reflected signal 432 are depicted as separate signals, it is noted that such signals can be referred to as a single signal. Moreover, ultrasound signal 422 and reflected signal 432 can comprise a different number of pulses due to some pulses of ultrasound signal 422 being absorbed, not reflected/refracted, reflected/refracted in a different direction, or the like. In another aspect, reflected signal 432 can be a relatively weaker signal due to attenuation through a medium (e.g., atmosphere, air, etc.) or other factors.

After some delay from transmission of ultrasound signal 422, reflected signal 432 can be received with some attenuation. Receiver 430 can receive the reflected signal 432 in a receiver path. The control switch 414 can isolate the transmitter path from the receiver path. It is noted that a controller (not shown) can control the timing or coordination of control switch 414. It is further noted that control switch 414 may be a high frequency switch. However, in at least one embodiment, the control switch 414 need not be a high frequency switch because it may take several milliseconds (e.g., depending on a traveled distance) between transmission and reception as the signals essentially travel twice distance 446.

Receiver 430 and/or receiver path can comprise an amplifier 438, a band pass filter 434, and an analog to digital converter (ADC) 436. When the reflected signal 432 is received, it can first pass through amplifier 438, which can amplify the received signal. The amplified signal can then pass through band pass filter 434. The amplified and filtered signal can then be received by ADC 436, which can convert the signal to a digital signal.

There is a possibility of cross talk between transmitter 420 and receiver 430. In at least one example, the cross talk may not be significant enough to affect the object detection process of the system 400. In other examples, the cross talk may be substantial, and a two-sensor system can be used to eliminate or reduce effects of the cross talk. It is noted that one-sensor and two-sensor systems may be utilized on a device, application, and/or user basis. In some embodiments, a system can switch between one-sensor and two-sensor systems, such as based on cross talk and/or performance (i.e., objective or subjective performance).

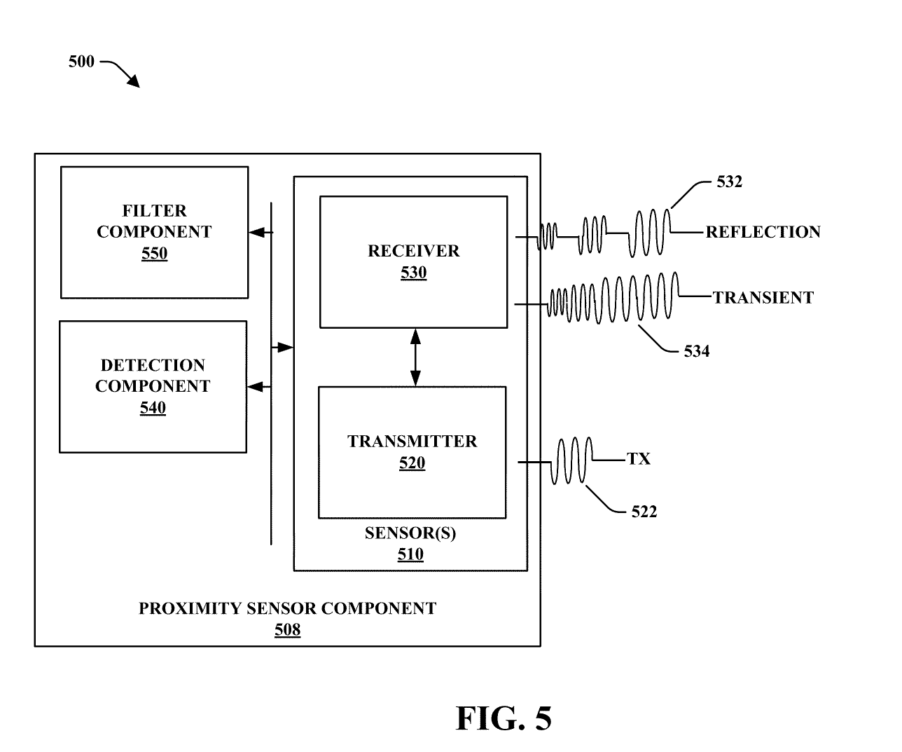

Referring now to FIG. 5, there illustrated is a system 500, including an acoustic sensor (e.g., MEMS microphone) that can determine proximity and filter a transient signal in accordance with various embodiments described herein. While, system 500 is depicted as comprising a number of components and/or circuitry, it is noted that system 500 can comprise various other components, circuitry, or other arrangements of circuitry/components (not shown). It is to be appreciated that system 500 can be used in connection with implementing one or more of the systems or components shown and described in connection with other figures disclosed herein (e.g., system 100, 200, 300, 400, etc.). Moreover, like named components associated with the various figures described herein can perform similar or identical functions and/or comprise similar or identical circuitry, logic, and the like. For example, detection component 540 can perform substantially similar functions as detection component 140.

As depicted, system 500 can primarily comprise a sensor(s) 510 (which can comprise transmitter 520 and receiver 530), a detection component 540, and a filter component 550. Transmitter 520 can generate pulse signal 522. In various embodiments, transmitter 520 can comprise a membrane, diaphragm, or other element capable of generating a pulse signal(s). For instance, transmitter 520 can be a microphone or a portion thereof. The microphone can comprise a membrane that, when vibrated or excited, can generate the pulse signal(s). When the membrane of the microphone is excited to generate the transmitted signal, it can take time for the membrane to become still. Thus, the membrane may not be completely still when some or all of the reflected signal 532 is received by receiver 530. Accordingly, the membrane may be in motion or oscillating when the reflected signal 532 is received and the motion can cause detection of a transient signal 534.

Filter component 550 can utilize filtering techniques to filter the transient signal 534 from a received input. Filter component 550 can comprise various components or circuitry such as a digital signal processor (DSP) filter, programmable filters, band pass filters (e.g., low frequency, high frequency, etc.), or the like. Such filters can filter unwanted signals from the received signals to eliminate and/or reduce effects of the transient signal. It is noted that filter component 550 can utilize any number of techniques, components, methods, and the like to filter received signals.

In at least one embodiment, filter component 550 can filter other received signals from the reflected signal 532. For instance, a user may be talking on a mobile device and/or in a crowded area having ambient noise or background noise. Filter component 550 can receive reflected signal 532 as well as signals from the ambient noise. As such, proximity sensor component 508 can determine proximity in the presence of other noises and/or ultrasound signals.

According to another embodiment, two or more devices can generate ultrasound signals for proximity detection. For example, two smart phones, a smart phone and another device, or the like, that each comprise at least one sensor (e.g., sensor(s) 510). For simplicity of explanation, this and other examples may refer to two smart phones (e.g., a first smart phone and a second smart phone) each having a proximity sensor component 508, however it is appreciated that various other devices can be utilized. The two smart phones can each generate pulse signals via their respective transmitters (e.g., transmitter 520) and receive signals via their respective receivers (e.g., 530). In embodiments, the smart phones can receive signals generated by the other smart phone. For instance, the first smart phone can generate ultrasonic signals that can be received by the second smart phone and the first smart phone. The second smart phone (e.g., via detection component 540) can detect the first smart phone based on receiving a signal from the first smart phone. Likewise, the second smart phone can determine a proximity to the first smart phone based on receiving a reflection of a signal transmitted by the second smart phone.

In another aspect, the second smart phone can filter (e.g., via filter component 550) the signal transmitted by the first smart phone from received signals. It is noted that the smart phones can each utilize a specific frequency, sequence of transmissions, amplitudes, or the like for their respective transmissions. Variations in parameters of transmissions can help distinguish signals associated with the respective smart phones. It is further noted that transmitted signals can comprise different frequencies and/or sequences. For instance, frequencies of transmissions can be altered per pulse, per set of pulses, and the like.

In at least one embodiment, system 500 can identify a source of a signal based on detected parameters of received transmissions. For instance, an identification protocol can establish a process for generating signals based on a type of device, a user identity associated with the device, or the like. For example, the identification protocol can be implemented such that smart phones generate signals in a first frequency range, while wearables (e.g., smart watches) generate signals in a second frequency range. In another aspect, the identification protocol can be utilized as a security protocol. The security protocol can identify devices based on parameters of transmissions. For instance, a user entity associated with a device may be assigned a specific set of parameters for generating a signal (e.g., frequency, pattern of signals, etc.). Identification of the specific parameters by a receiving device can authenticate (or otherwise affect security for) the user. It is noted that the security protocol can be applied to a device, a user entity, a combination of a device and user entity, or the like.

While several example embodiments are provided, it is noted that aspects of this disclosure are not limited to the exemplary embodiments. As such, the various embodiments disclosed herein can be applied to numerous applications. In exemplary embodiments, systems and methods described herein can be applied to smart phones, hand held gaming devices, hand held electronics, notebook computers, desktop computers, and the like. Such systems can be utilized to determine proximity to control various functions, such as standby-mode activation/de-activation, interface (e.g., keypad backlight, view screen, etc.) activation/deactivation, speakerphone activation/deactivation, volume adjustments, or the like. In at least one other embodiment, various systems disclosed can be included within a digital camera, smart camera, or the like. For example, a camera can control a display (e.g., monitor, touch screen, etc.) based on determining whether a user is in proximity with a viewfinder. If a user is utilizing a viewfinder, the display can be turned off, and/or dimmed. In another aspect, aspects of the camera can be controlled, based on proximity detection, to eliminate eye glare. It is further noted, that proximity detection systems disclosed herein can be utilized as “buttons” or non-pressured buttons, such as for autofocus of a camera system (e.g., wherein proximity can be near zero). In another example, embodiments disclosed herein can be incorporated in wearable electronics, such as headphones (e.g., turn on/off based on proximity).

Various other embodiments can utilize systems and methods described herein in applications, such as, but not limited to, home appliances, printing devices, industrial systems, automotive systems, navigation systems, global positioning satellite (GPS) systems, and the like. In an aspect, home appliances can include irons (which can turn on/off based on proximity detection), power tools, hair care machines (e.g., hair iron, blow dryer), refrigerators, coffee machines (or other beverage machines which can detect a cup for dispensing a liquid), robotic vacuum machines (which can navigate around objects based on proximity detection), and the like. In another aspect, industrial and automotive applications can include applications that utilize gesture controlled switches, automated faucets, automated toilets, automated hand drying machines, mechanical switches, disc detection systems (e.g., in energy meters), and the like. While various examples have been described, it is noted that aspects of the subject disclosure described herein can be applied to many other applications.

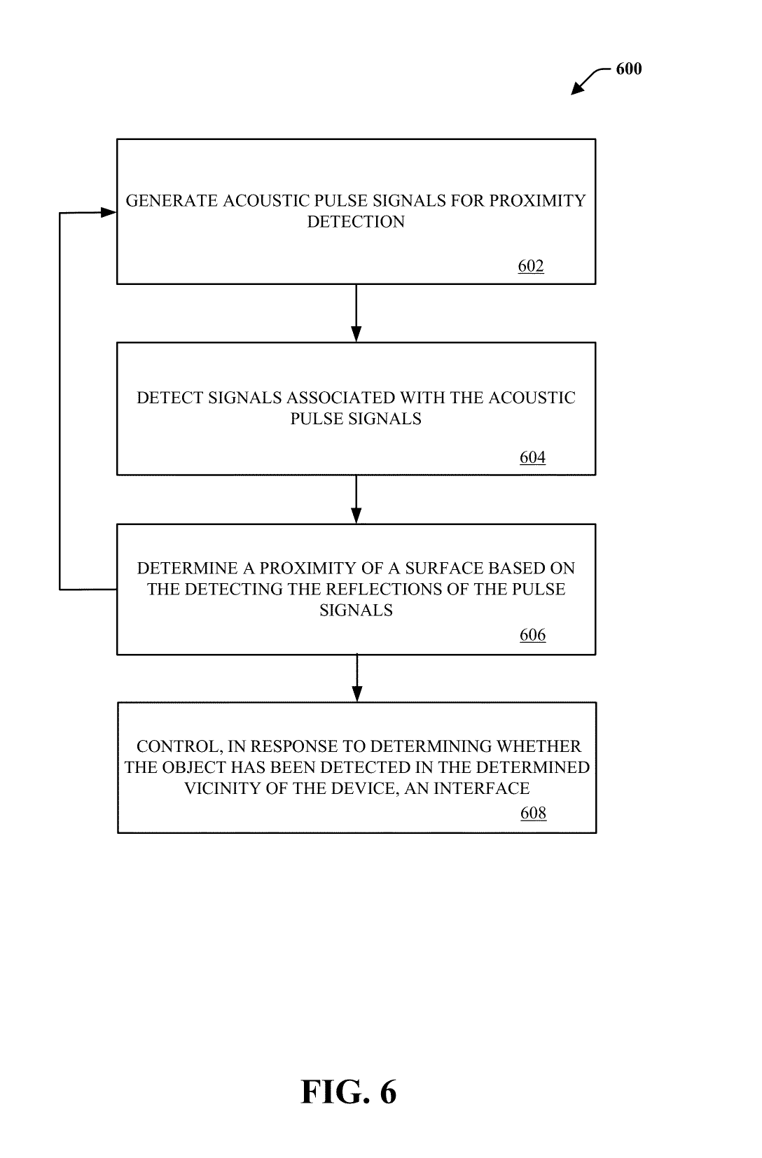

In view of the subject matter described supra, methods that can be implemented in accordance with the subject disclosure will be better appreciated with reference to the flowcharts of FIGS. 6-9. While for purposes of simplicity of explanation, the methods are shown and described as a series of blocks, it is to be understood and appreciated that such illustrations or corresponding descriptions are not limited by the order of the blocks, as some blocks may occur in different orders and/or concurrently with other blocks from what is depicted and described herein. Any non-sequential, or branched, flow illustrated via a flowchart should be understood to indicate that various other branches, flow paths, and orders of the blocks, can be implemented which achieve the same or a similar result. Moreover, not all illustrated blocks may be required to implement the methods described hereinafter.

### Exemplary Methods

FIG. 6 depicts an exemplary flowchart of non-limiting method 600 associated with a proximity detection system, according to various non-limiting aspects of the subject disclosure. As a non-limiting example, exemplary methods 600 can comprise determining a proximity of a surface utilizing a MEMS acoustic sensor system (e.g., system 100, 200, etc.).

At 602, a system (e.g., system 100) can generate (e.g., via transmitter 120) acoustic pulse signals for proximity detection. In embodiments, the acoustic pulse signals are generated for at least one of reflection off a surface or reception by another device. In various embodiments, the system can generate the pulse signals as a plurality of ultrasonic pulses and/or audio pulses. The system can generate dynamically determined or a predetermined determined number of pulse signals. While method 600 describes generating pulse signals for reflection off a surface, it is noted that the pulse signals need not be reflected off a surface. For example, the pulse signals can be generated for detection by another device.

At 604, the system can detect (e.g., via receiver 130 and/or detection component 140) signals associated with the acoustic pulse signals. In an aspect, the detected signals can the reflection (or partial reflection) of the acoustic pulse signals off the surface. In accordance with various embodiments described herein, the surface can be any surface, object, or the like. In another aspect, detecting the reflected signals can comprise filtering other signals (e.g., transient signals, ambient signals, etc.) from received signals. Moreover, the system can detect or count a number of pulses associated with the reflected signals.

At 606, the system can determine (e.g., via detection component 140) a proximity of a surface based on the detecting the reflections of the pulse signals. In at least one embodiment, the system can count a number of pulses associated with detected signals, determine a time associated with detection of signals (e.g., time from generation of signals to detection of signals, etc.), or determine other parameters of the detected signals. For example, based on the number of pulses meeting a threshold or being between upper and lower bounds of a threshold range, the system can determine a proximity of the surface relative to a device (e.g., a device comprising system 100).

In another aspect, the system can continue to 602 and/or 608. In an aspect, continuing to 602 and 608 can be performed simultaneously, substantially simultaneously, upon triggering events, or the like. For instance, the system can iterate transmitting the generating the pulse signals, detecting reflected signals associated with the reflection of the pulse signals, and the determining the proximity of the surface as long as a device is in use. In at least one embodiment, the system can be in an “always on” mode where the system repeatedly iterates the transmitting, receiving, and determining. In other embodiments, the system can be in an active or not active mode. For instance, a cellular phone may be in an active mode when the cellular phone is not sleeping or is engaged in a particular activity (e.g., a call, playing a video, etc.). That is, the system can iterate the proximity detection process when a user is engaging in an activity with the cellular phone. Further, if the cellular phone is in a sleep mode (i.e., due to a period of inactivity) then the system can enter a not active mode where the proximity detection is not iterated.

It is noted that an “active” mode and/or “not active” mode are utilized for exemplary purposes. As such, various embodiments can utilize a different number of modes that are based on various triggering events or factors. It is further noted that the system can alter modes based on user defined rules, predefined or default rules, dynamically determined rules (e.g., rules determined based on a machine learning process), or the like.

At 608, the system can control (e.g., via detection component 140, calibration component 360, etc.), in response to determining whether the object has been detected in the determined vicinity of the device, an interface. The interface can comprise a computer monitor, a touch screen, a display device, a light emitting diode (LED) indicator, or other interface device. As an example, a mobile device can comprise the system, and if the system determines the object is detected in the vicinity, then the system can lock or disable an interface of the mobile device. It is noted that various control rules can be utilized, such that the device's interface is locked during a call, unlocked when in speaker mode, or the like.

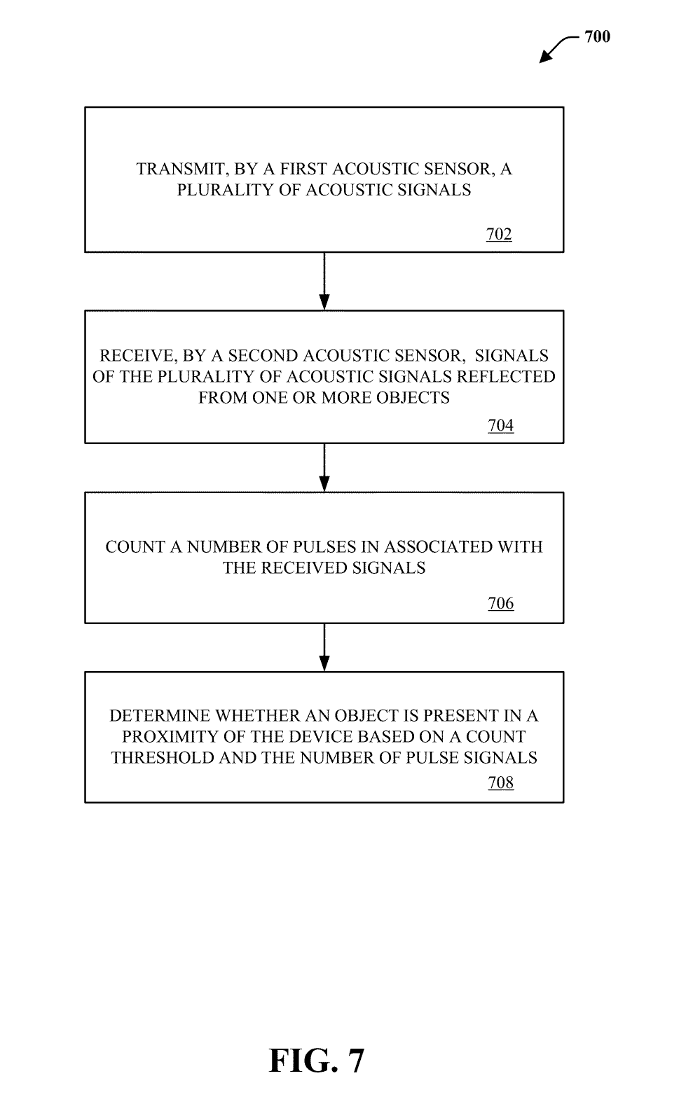

FIG. 7 depicts an exemplary flowchart of non-limiting method 700 associated with a two-sensor proximity detection system, according to various non-limiting aspects of the subject disclosure. As a non-limiting example, exemplary methods 700 can comprise determining a proximity of a surface utilizing a two MEMS acoustic sensor system (e.g., system 100, 200, etc.).

At 702, a system (e.g., system 100, 200, etc.) can transmit, by a first acoustic sensor (e.g., a sensor comprising transmitter 130), a plurality of acoustic signals. The first acoustic sensor can comprise a microphone, such as a MEMS microphone. As described herein, the plurality of acoustic signals can comprise a set of pulse in a determined frequency. It is noted that each pulse can be of a common or distinct frequency.

At 704, the system can receive, by a second acoustic sensor (e.g., a sensor comprising receiver 130) signals of the plurality of acoustic signals reflected from one or more objects. As above, the second acoustic sensor can comprise a microphone, such as a MEMS microphone. Moreover, the first and the second acoustic sensors can be dedicated to a specific function (e.g., transmitting or receiving) or programmably configured to perform a specific function. As such, the first and the second acoustic sensors can each be configured as a transmitter and/or receiver.

At 706, the system can count (e.g., via detection component 140) a number of pulses associated with the received signals. For example, the count can be a number of pulses received in a determined period, such as a period beginning from when a signal is transmitted and ending after a predetermined time. At 708, the system can determine (e.g., via detection component 140) whether an object is present in a proximity of the device based on a count threshold and the number of pulse signals. The received pulses can correspond to a relative proximity. Various thresholds or ranges can be applied to determine a proximity. The thresholds can comprise numbers of pulses and/or percentages. As a simplistic example, if 75% or more of a range of is reached, the system can determine that an object is in a close proximity. If less than 75% of the range is reached, the system can determine that the object is far (i.e., not near).

While counting of received pulse signals is described, it is appreciated that various embodiments can utilize other proximity determining processes, such as counting clock pulses (e.g., time of flight, etc.). Moreover, embodiments described herein can selectively utilize different proximity determining processes that are selected based on, for example, a performance metric (e.g., power consumption, sensitivity, subjective/objective analysis, etc.), a calibration process, user input, or the like.

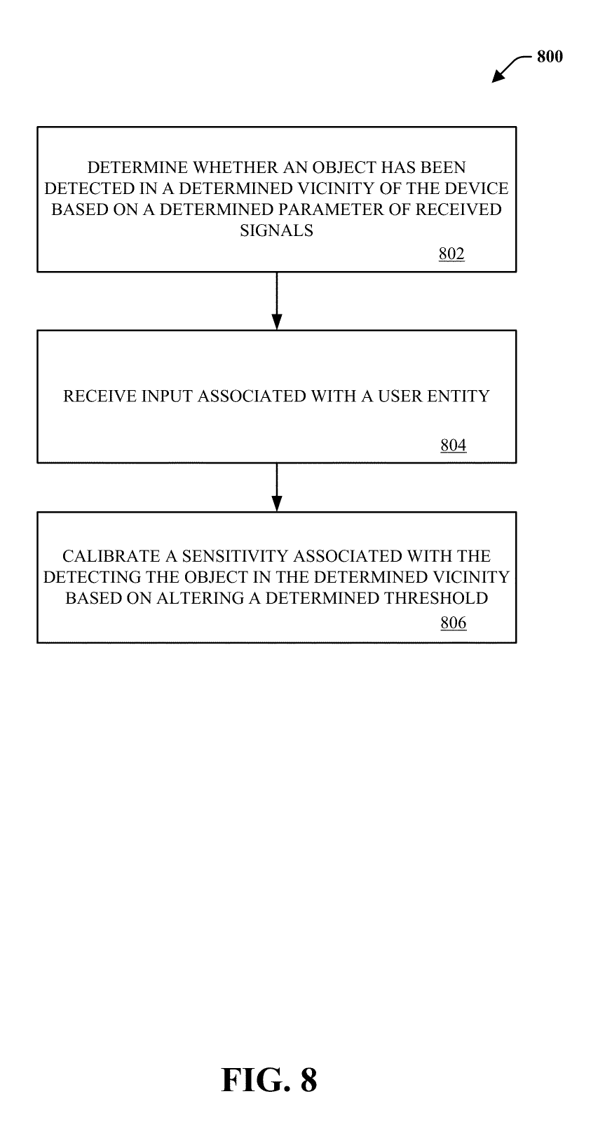

FIG. 8 depicts an exemplary flowchart of non-limiting method 800 associated with calibrating a proximity detection system, according to various non-limiting aspects of the subject disclosure. As a non-limiting example, exemplary methods 800 can comprise calibrating a proximity detection process utilizing a MEMS acoustic sensor system (e.g., system 100, 200, etc.). At 802, a system (e.g., system 300) can determine (e.g., via detection component 340) whether an object has been detected in a determined vicinity of the device based on a determined parameter of received signals, such as a pulse count, time information, or the like.

At 804, the system can receive input associated with a user entity. The input can be received via an interface, from a remote computer, from a memory device, or the like. In an aspect, the input can be in various forms depending on desired implementations.

At 806, the system can calibrate (e.g., via calibration component 360) a sensitivity associated with the detecting the object in the determined vicinity based on altering a determined threshold. Altering the determined threshold can include setting a particular threshold, dynamically determining a threshold based on objective/subjective analysis, or the like. The altered threshold can be stored (e.g., in a memory) for later use. In various embodiments, the system can determine to dynamically alter a threshold based on information associated with a history of use.

The systems and processes described below can be embodied within hardware, such as a single integrated circuit (IC) chip, multiple ICs, an ASIC, or the like. Further, the order in which some or all of the process blocks appear in each process should not be deemed limiting. Rather, it should be understood that some of the process blocks can be executed in a variety of orders, not all of which may be explicitly illustrated herein.

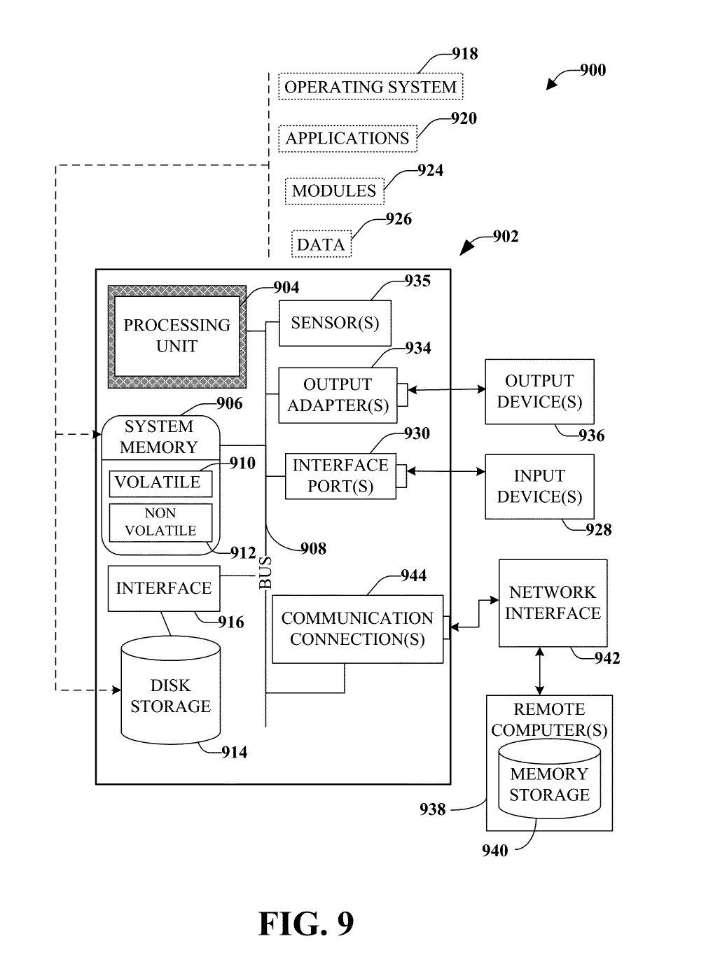

With reference to FIG. 9, a suitable environment 900 for implementing various aspects of the claimed subject matter includes a computer 902. The computer 902 includes a processing unit 904, a system memory 906, sensor(s) 935 (e.g., acoustic sensor(s), pressure sensor(s), temperature sensor(s), etc.), and a system bus 908. The system bus 908 couples system components including, but not limited to, the system memory 906 to the processing unit 904. The processing unit 904 can be any of various available processors. Dual microprocessors and other multiprocessor architectures also can be employed as the processing unit 904.

The system bus 908 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Personal Computer Memory Card International Association bus (PCMCIA), Firewire (IEEE 1394), and Small Computer Systems Interface (SCSI).

The system memory 906 includes volatile memory 910 and non-volatile memory 912. The basic input/output system (BIOS), containing the basic routines to transfer information between elements within the computer 902, such as during start-up, is stored in non-volatile memory 912. In addition, according to present innovations, sensor(s) 935 may include at least one audio sensor (e.g., MEMS microphone, etc.). Wherein the at least one audio sensor(s) may consist of hardware, software, or a combination of hardware and software. Although, sensor(S) 935 is depicted as a separate component, sensor(s) 935 may be at least partially contained within non-volatile memory 912. By way of illustration, and not limitation, non-volatile memory 912 can include read only memory (ROM), programmable ROM (PROM), electrically programmable ROM (EPROM), electrically erasable programmable ROM (EEPROM), or flash memory. Volatile memory 910 includes random access memory (RAM), which acts as external cache memory. According to present aspects, the volatile memory may store the write operation retry logic (not shown in FIG. 9) and the like. By way of illustration and not limitation, RAM is available in many forms such as static RAM (SRAM), dynamic RAM (DRAM), synchronous DRAM (SDRAM), double data rate SDRAM (DDR SDRAM), and enhanced SDRAM (ESDRAM.

Computer 902 may also include removable/non-removable, volatile/non-volatile computer storage medium. FIG. 9 illustrates, for example, disk storage 914. Disk storage 914 includes, but is not limited to, devices like a magnetic disk drive, solid state disk (SSD) floppy disk drive, tape drive, Jaz drive, Zip drive, LS-100 drive, flash memory card, or memory stick. In addition, disk storage 914 can include storage medium separately or in combination with other storage medium including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage devices 914 to the system bus 908, a removable or non-removable interface is typically used, such as interface 916. It is appreciated that storage devices 914 can store information related to a user. Such information might be stored at or provided to a server or to an application running on a user device. In one embodiment, the user can be notified (e.g., by way of output device(s) 936) of the types of information that are stored to disk storage 914 and/or transmitted to the server or application. The user can be provided the opportunity to control having such information collected and/or shared with the server or application by way of input from input device(s) 928).

It is to be appreciated that FIG. 9 describes software that acts as an intermediary between users and the basic computer resources described in the suitable operating environment 900. Such software includes an operating system 918. Operating system 918, which can be stored on disk storage 914, acts to control and allocate resources of the computer system 902. Applications 920 take advantage of the management of resources by operating system 918 through program modules 924, and program data 926, such as the boot/shutdown transaction table and the like, stored either in system memory 906 or on disk storage 914. It is to be appreciated that the claimed subject matter can be implemented with various operating systems or combinations of operating systems.

A user enters commands or information into the computer 902 through input device(s) 928. Input devices 928 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 904 through the system bus 908 via interface port(s) 930. Interface port(s) 930 include, for example, a serial port, a parallel port, a game port, and a universal serial bus (USB). Output device(s) 936 use some of the same type of ports as input device(s) 928. Thus, for example, a USB port may be used to provide input to computer 902 and to output information from computer 902 to an output device 936. Output adapter 934 is provided to illustrate that there are some output devices 936 like monitors, speakers, and printers, among other output devices 936, which require special adapters. The output adapters 934 include, by way of illustration and not limitation, video and sound cards that provide a means of connection between the output device 936 and the system bus 908. It should be noted that other devices and/or systems of devices provide both input and output capabilities such as remote computer(s) 938.

Computer 902 can operate in a networked environment using logical connections to one or more remote computers, such as remote computer(s) 938. The remote computer(s) 938 can be a personal computer, a server, a router, a network PC, a workstation, a microprocessor based appliance, a peer device, a smart phone, a tablet, or other network node, and typically includes many of the elements described relative to computer 902. For purposes of brevity, only a memory storage device 940 is illustrated with remote computer(s) 938. Remote computer(s) 938 is logically connected to computer 902 through a network interface 942 and then connected via communication connection(s) 944. Network interface 942 encompasses wire and/or wireless communication networks such as local-area networks (LAN) and wide-area networks (WAN) and cellular networks. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL).

Communication connection(s) 944 refers to the hardware/software employed to connect the network interface 942 to the bus 908. While communication connection 944 is shown for illustrative clarity inside computer 902, it can also be external to computer 902. The hardware/software necessary for connection to the network interface 942 includes, for exemplary purposes only, internal and external technologies such as, modems including regular telephone grade modems, cable modems and DSL modems, ISDN adapters, and wired and wireless Ethernet cards, hubs, and routers.

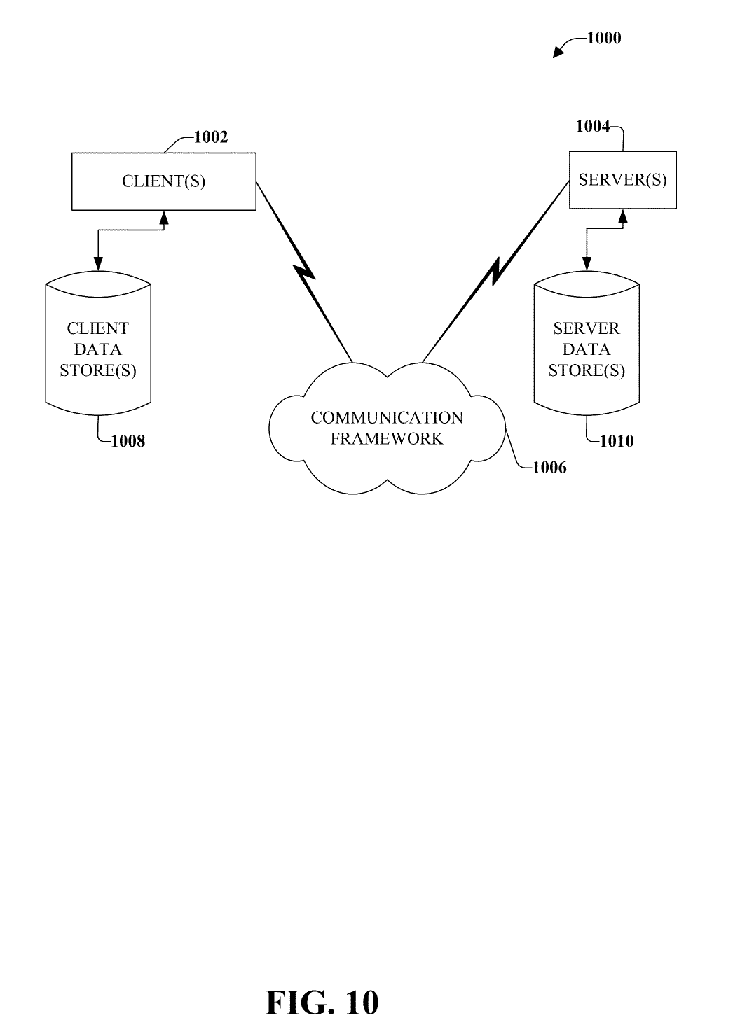

Referring now to FIG. 10, there is illustrated a schematic block diagram of a computing environment 1000 in accordance with this specification. The system 1000 includes one or more client(s) 1002 that may comprise a proximity sensing system according to various embodiments disclosed herein (e.g., laptops, smart phones, PDAs, media players, computers, portable electronic devices, tablets, and the like). The client(s) 1002 can be hardware and/or software (e.g., threads, processes, computing devices). The system 1000 also includes one or more server(s) 1004. The server(s) 1004 can also be hardware or hardware in combination with software (e.g., threads, processes, computing devices). The servers 1004 can house threads to perform transformations by employing aspects of this disclosure, for example. One possible communication between a client 1002 and a server 1004 can be in the form of a data packet transmitted between two or more computer processes wherein the data packet may include sensor data, proximity data, user defined rules, and the like. The data packet can include a cookie and/or associated contextual information, for example. The system 1000 includes a communication framework 1006 (e.g., a global communication network such as the Internet, or mobile network(s)) that can be employed to facilitate communications between the client(s) 1002 and the server(s) 1004.

Communications can be facilitated via a wired (including optical fiber) and/or wireless technology. The client(s) 1002 are operatively connected to one or more client data store(s) 1008 that can be employed to store information local to the client(s) 1002 (e.g., cookie(s) and/or associated contextual information). Similarly, the server(s) 1004 are operatively connected to one or more server data store(s) 1010 that can be employed to store information local to the servers 1004.

In one embodiment, a client 1002 can transfer an encoded file, in accordance with the disclosed subject matter, to server 1004. Server 1004 can store the file, decode the file, or transmit the file to another client 1002. It is to be appreciated, that a client 1002 can also transfer uncompressed file to a server 1004 and server 1004 can compress the file in accordance with the disclosed subject matter. Likewise, server 1004 can encode information and transmit the information via communication framework 1006 to one or more clients 1002.

The illustrated aspects of the disclosure may also be practiced in distributed computing environments where certain tasks are performed by remote processing devices that are linked through a communications network. In a distributed computing environment, program modules can be located in both local and remote memory storage devices.

Moreover, it is to be appreciated that various components described herein can include electrical circuit(s) that can include components and circuitry elements of suitable value in order to implement the embodiments of the subject innovation(s). Furthermore, it can be appreciated that many of the various components can be implemented on one or more integrated circuit (IC) chips. For example, in one embodiment, a set of components can be implemented in a single IC chip. In other embodiments, one or more of respective components are fabricated or implemented on separate IC chips.

What has been described above includes examples of the embodiments of the present disclosure. It is, of course, not possible to describe every conceivable combination of components or methodologies for purposes of describing the claimed subject matter, but it is to be appreciated that many further combinations and permutations of the subject innovation are possible. Accordingly, the claimed subject matter is intended to embrace all such alterations, modifications, and variations that fall within the spirit and scope of the appended claims. Moreover, the above description of illustrated embodiments of the subject disclosure, including what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize. Moreover, use of the term “an embodiment” or “one embodiment” throughout is not intended to mean the same embodiment unless specifically described as such.

In particular and in regard to the various functions performed by the above described components, devices, circuits, systems and the like, the terms used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the claimed subject matter. In this regard, it will also be recognized that the innovation includes a system as well as a computer-readable storage medium having computer-executable instructions for performing the acts and/or events of the various methods of the claimed subject matter.

The aforementioned systems/circuits/modules have been described with respect to interaction between several components/blocks. It can be appreciated that such systems/circuits and components/blocks can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it should be noted that one or more components may be combined into a single component providing aggregate functionality or divided into several separate sub-components, and any one or more middle layers, such as a management layer, may be provided to communicatively couple to such sub-components in order to provide integrated functionality. Any components described herein may also interact with one or more other components not specifically described herein but known by those of skill in the art.

In addition, while a particular feature of the subject innovation may have been disclosed with respect to only one of several implementations, such feature may be combined with one or more other features of the other implementations as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

As used in this application, the terms “component,” “module,” “system,” or the like are generally intended to refer to a computer-related entity, either hardware (e.g., a circuit), a combination of hardware and software, software, or an entity related to an operational machine with one or more specific functionalities. For example, a component may be, but is not limited to being, a process running on a processor (e.g., digital signal processor), a processor, an object, an executable, a thread of execution, a program, and/or a computer. By way of illustration, both an application running on a controller and the controller can be a component. One or more components may reside within a process and/or thread of execution and a component may be localized on one computer and/or distributed between two or more computers. Further, a “device” can come in the form of specially designed hardware; generalized hardware made specialized by the execution of software thereon that enables the hardware to perform specific function; software stored on a computer readable medium; or a combination thereof.

Moreover, the words “example” or “exemplary” are used herein to mean serving as an example, instance, or illustration. Any aspect or design described herein as “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Computing devices typically include a variety of media, which can include computer-readable storage media and/or communications media, in which these two terms are used herein differently from one another as follows. Computer-readable storage media can be any available storage media that can be accessed by the computer, is typically of a non-transitory nature, and can include both volatile and nonvolatile media, removable and non-removable media. By way of example, and not limitation, computer-readable storage media can be implemented in connection with any method or technology for storage of information such as computer-readable instructions, program modules, structured data, or unstructured data. Computer-readable storage media can include, but are not limited to, RAM, ROM, EEPROM, flash memory or other memory technology, CD-ROM, digital versatile disk (DVD) or other optical disk storage, magnetic cassettes, magnetic tape, magnetic disk storage or other magnetic storage devices, or other tangible and/or non-transitory media which can be used to store desired information. Computer-readable storage media can be accessed by one or more local or remote computing devices, e.g., via access requests, queries or other data retrieval protocols, for a variety of operations with respect to the information stored by the medium.

On the other hand, communications media typically embody computer-readable instructions, data structures, program modules or other structured or unstructured data in a data signal that can be transitory such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

What is claimed is:

1. A system comprising a microelectromechanical systems (MEMS) acoustic sensor, the system comprising:
a transmitter configured to transmit a plurality of acoustic pulse signals;
a receiver configured to detect signals associated with the plurality of acoustic pulse signals; and
a processor communicably coupled to the receiver and configured to determine whether an object has been detected in a determined vicinity of the system based on a parameter of the detected signals.

2. The system of claim 1, wherein the parameter of the detected signals is a time of flight parameter, and wherein the processor is further configured to determine whether the object has been detected in the determined vicinity based on the time of flight parameter.

3. The system of claim 1, wherein the parameter of the detected signals is at least one of a signal energy parameter or amplitude parameter associated with the detected signals, and wherein the processor is further configured to determine whether the object has been detected in the proximity based on at least one of the signal energy parameter or the amplitude parameter.

4. The system of claim 1, wherein the plurality of acoustic pulse signals includes ultrasound pulse signals.

5. The system of claim 1, wherein the MEMS acoustic sensor comprises an acoustic sensor element coupled to an application specific integrated circuit (ASIC).

6. The system of claim 5, wherein the ASIC includes the processor and the receiver.

7. The system of claim 1, wherein the processor is further configured to determine that the object has been detected in the determined vicinity of the system based on a count of the detected pulse signals meeting a determined threshold.

8. The system of claim 1, wherein the processor is further configured to determine that the object has been detected in the determined vicinity based on a search process that compares the parameter to parameters stored in a memory.

9. The system of claim 7, wherein the processor is further configured to calibrate a sensitivity associated with the detecting the object in the determined vicinity based on altering the determined threshold.

10. The system of claim 9, wherein the processor is further configured to alter the determined threshold based on received input associated with a user.

11. The system of claim 1, wherein the processor is further configured to calibrate a sensitivity associated with the detecting the object in the determined vicinity based on altering a parameter of the plurality of acoustic pulse signals.

12. The system of claim 1, wherein the processor is further configured to control, in response to determining whether the object has been detected in the determined vicinity of the system, an interface coupled to the processor.

13. The system of claim 1, wherein the receiver is further configured to detect a different plurality of pulse signals associated with an external transmitter associated with a disparate device; and
wherein the processor is further configured to detect the disparate device based on the different plurality of pulse signals.

14. The system of claim 1, wherein the MEMS acoustic sensor comprises the receiver and further comprising another MEMS acoustic sensor communicably coupled to the processor and comprising the transmitter.

15. The system of claim 1, wherein the parameter is a time associated with receiving at least a portion of the detected signals, and wherein the processor is further configured to determine whether the object has been detected in the determined vicinity of the system based on the time associated with receiving at least the portion of the detected signals.

16. A device comprising:
a first acoustic sensor for transmitting a plurality of acoustic signals;
a second acoustic sensor for receiving signals associated with the plurality of acoustic signals;
a proximity sensor component communicably coupled to the second acoustic sensor and configured to determine a parameter of the received signals; and
a processor communicably coupled to the proximity sensor component and configured to determine whether an object is present in a proximity of the device based on a threshold and the parameter of the received signals.

17. The device of claim 16, wherein the first acoustic sensor is configured for transmitting the plurality of acoustic signals at frequencies in a range of twenty two kilohertz (kHz) to 85 kHz.

18. The device of claim 16, wherein the processor is further configured to iterate the determining whether the object is present during an active mode associated with the device.

19. The device of claim 16, wherein the processor is further configured to determine whether the object is present in a first proximity associated with a first threshold or in a second proximity associated with a second threshold.

20. The device of claim 16, further comprising a filter component configured to extract a transient signal from the received signals.

21. A method associated with a microelectromechanical systems (MEMS) microphone comprising:
generating, by the MEMS microphone, pulse signals for reflection off a surface;
detecting reflected signals associated with the reflection of the pulse signals of the surface; and
determining a proximity of the surface based on the detecting the reflections of the pulse signals.

22. The method of claim 21, wherein the determining the proximity of the surface determines the proximity as one of a near proximity or a far proximity.

23. The method of claim 21, further comprising:
determining an orientation associated with a device comprising the MEMS microphone, and
wherein the determining the proximity of the surface utilizes a proximity determining process selected, based on the orientation, from a set of proximity determining processes.

24. The method of claim 21, further comprising determining the proximity of the surface based on the detecting the reflections of the pulse signals and time of flight information associated with the reflections.

26. The method of claim 21, further comprising:
calibrating the determining the proximity of the surface based on a user defined rule.
